(19) United States
(12) Patent Application Publication
(10) Pub. No.: US 2025/0158581 A1
(43) Pub. Date: May 15, 2025

(54) POWER AMPLIFIER, RADIO FREQUENCY GENERATOR, AND WIRELESS POWER TRANSMISSION DEVICE

(71) Applicant: Samsung Electronics Co., Ltd., Suwon-si (KR)

(72) Inventors: Sunwoo Nam, Suwon-si (KR); Youngoo Yang, Suwon-si (KR)

(73) Assignees: Samsung Electronics Co., Ltd., Suwon-si (KR); RESEARCH AND BUSINESS FOUNDATION SUNGKYUNKWAN UNIVERSITY, Suwon-si (KR)

(21) Appl. No.: 18/937,506

(22) Filed: Nov. 5, 2024

(30) Foreign Application Priority Data
Nov. 10, 2023 (KR) 10-2023-0155718

(51) Int. Cl. H03F 3/24; H01J 37/32; H02J 50/10

(52) U.S. Cl. CPC H03F 3/245; H01J 37/32183; H02J 50/10; H03F 2200/451

(57) ABSTRACT

Provided is a power amplifier having improved band characteristics. The power amplifier includes a switch circuit including a transistor configured to be turned on or turned off, based on an input signal, a filter circuit connected between an output terminal of the transistor and a ground, and a multi-resonant circuit connected to the output terminal of the transistor and one end of the filter circuit and including a plurality of series resonant circuits, the plurality of series resonant circuits having different resonant frequencies from each other and being connected in parallel to each other.

### CROSS-REFERENCE TO RELATED APPLICATION

This application is based on and claims priority under 35 U.S.C. § 119 to Korean Patent Application No. 10-2023-0155718, filed on Nov. 10, 2023, in the Korean Intellectual Property Office, the disclosure of which is incorporated by reference herein in its entirety.

### BACKGROUND

The present disclosure relates to a power amplifier, a radio frequency (RF) generator, and a wireless power transmission device.

Wireless power transmission technology is used to wirelessly supply power to electronic devices. Recently, due to the development of wireless charging technology, methods of charging by supplying power from one electronic device (wireless power transmission device) to various other electronic devices (wireless power reception devices) have been researched. For example, wireless charging technology includes an electromagnetic induction method using a coil, a resonance method using resonance, and an RF/microwave radiation method for converting electrical energy into microwaves and transmitting the microwaves.

Wireless power transmission devices may include class E power amplifiers and class EF2 power amplifiers. In class E power amplifiers and class EF2 power amplifiers, serially connected resonant circuits are designed to resonate at an operating frequency and operate as short circuits at the operating frequency. However, because the resonant circuits do not operate as short circuits in a peripheral band of the operating frequency, performance degradation may occur in the peripheral band of the operating frequency.

### SUMMARY

The present disclosure provides a power amplifier having improved band characteristics, a radio frequency (RF) generator, and a wireless power transmission device.

The objective of the present disclosure is not limited to those mentioned above, and other objectives will be clearly understood by those skilled in the art from the following descriptions.

According to an aspect of the present disclosure, there is provided a power amplifier including a switch circuit including a transistor configured to be turned on or turned off in response to an input signal, a filter circuit connected between an output terminal of the transistor and a ground, and a multi-resonant circuit connected to the output terminal of the transistor and one end of the filter circuit and including a plurality of series resonant circuits, the plurality of series resonant circuits having different resonant frequencies from each other and being connected in parallel to each other.

According to an aspect of the present disclosure, there is provided a wireless power transmission device including a power amplifier including a switch circuit, a filter circuit, and a multi-resonant circuit and configured to convert a direct current received from an input power source into an alternating current having an operating frequency and perform zero voltage switching (ZVS), a power transmission circuit including a transmission coil configured to transmit power received from the power amplifier to outside, and a matching network connected between the power amplifier and the power transmission circuit and configured to match an impedance of the power amplifier with an impedance of the power transmission circuit, wherein the multi-resonant circuit is connected between one end of the filter circuit and one end of the matching network and includes a plurality of series resonant circuits, the plurality of series resonant circuits having different resonant frequencies from each other and being connected in parallel to each other.

According to an aspect of the present disclosure, there is provided an RF generator including a power amplifier including a switch circuit, a filter circuit, and a multi-resonant circuit and configured to convert a direct current received from an input power source into an alternating current having an operating frequency and perform ZVS, and a matching network connected between the power amplifier and a semiconductor process chamber and configured to match an impedance of the power amplifier to an impedance of the semiconductor process chamber, wherein the multi-resonant circuit is connected between one end of the filter circuit and one end of the matching network and includes a plurality of series resonant circuits, the plurality of series resonant circuits having different resonant frequencies from each other and being connected in parallel to each other.

### BRIEF DESCRIPTION OF THE DRAWINGS

Embodiments will be more clearly understood from the following detailed description taken in conjunction with the accompanying drawings in which:

FIG. 1 is a block diagram illustrating components of a power amplifier according to an embodiment;

FIG. 2 is a diagram illustrating components of a power amplifier according to an embodiment;

FIG. 3 is a diagram illustrating a wireless power transmission device including a power amplifier, according to an embodiment;

FIG. 4 is a diagram illustrating a radio frequency (RF) generator including a power amplifier, according to an embodiment;

FIG. 5A is a Smith chart illustrating a power contour and an efficiency contour according to frequency in a class E power amplifier of the related art;

FIG. 5B is a Smith chart illustrating a power contour and an efficiency contour according to frequency in a power amplifier according to an embodiment;

FIG. 6 is a diagram illustrating efficiency and power of a power amplifier according to frequency of the power amplifier according to an embodiment;

FIG. 7 is a diagram illustrating amplitude magnitudes of drain voltages of a class E power amplifier and a power amplifier according to an embodiment;

FIG. 8 is a diagram illustrating a harmonic output power level according to frequency of a power amplifier according to an embodiment;

FIG. 9 is a diagram illustrating components of a filter circuit included in a power amplifier, according to an embodiment;

FIG. 10 is a diagram illustrating components of a matching network connected to a power amplifier, according to an embodiment; and

FIG. 11 is a block diagram illustrating a wireless power transmission device and a wireless power reception device, according to an embodiment.

### DETAILED DESCRIPTION OF THE EMBODIMENTS

Hereinafter, embodiments of the present disclosure will be described in detail with reference to the accompanying drawings. The same reference numerals are used for the same components in the drawings, and redundant descriptions thereof will be omitted.

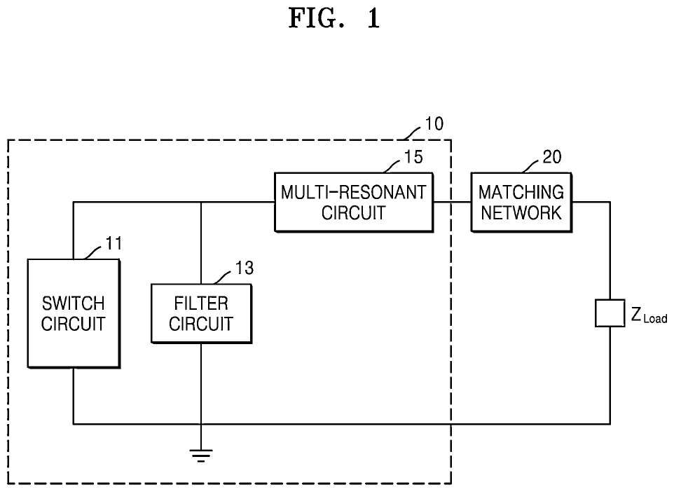

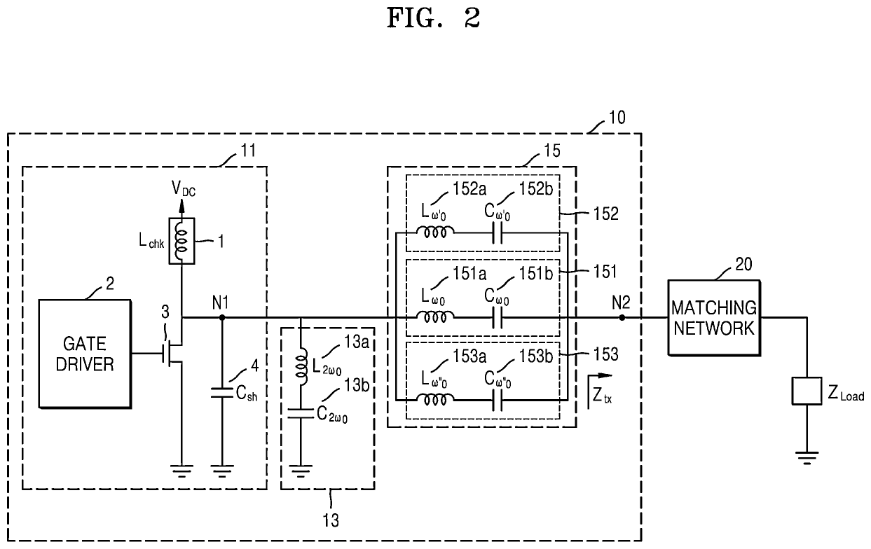

FIG. 1 is a block diagram illustrating components of a power amplifier 10 according to an embodiment, and FIG. 2 is a diagram illustrating in detail the components of the power amplifier 10 according to an embodiment.

Referring to FIG. 1, the power amplifier 10 may include a switch circuit 11, a filter circuit 13, and a multi-resonant circuit 15. A matching network 20 may be connected to an output terminal of the power amplifier 10, and a signal (or radio frequency (RF) power) generated by the power amplifier 10 may be transmitted to a load through the matching network 20.

Referring to FIGS. 1 and 2, the switch circuit 11 may include an RF choke inductor (L_{chk}) 1, a gate driver 2, a transistor 3, and a shunt capacitor (Cₛₕ) 4. The power amplifier 10 according to an embodiment may use a soft switching technique. The soft switching technique may include a zero current switching (ZCS) method and a zero voltage switching (ZVS) method. The transistor 3 in the switch circuit 11 may be a switch for implementing soft switching by the ZVS method.

The transistor 3 may operate by receiving a direct current (DC) voltage as a driving voltage V_{DC} from an input power source. The gate driver 2 may generate a driver signal to drive the transistor 3 of the switch circuit 11. The transistor 3 may be turned on or turned off by receiving an input signal in the form of a pulse from the gate driver 2 through an input terminal. For example, the transistor 3 may be turned on or turned off by receiving a square wave input signal from the gate driver 2 through a gate. The transistor 3 may output a signal corresponding to a set operating frequency, based on the driving voltage V_{DC} and the input signal. For example, the transistor 3 may receive the driving voltage V_{DC} and output, in response to the input signal, a signal corresponding to the set operating frequency (e.g., an RF signal). In an embodiment, the driver signal generated from the gate driver 2 may be a square wave signal having the set operation frequency, and the signal outputted from the transistor 3 may have the set operating frequency.

The transistor 3 may include or may be a metal-oxide-semiconductor field-effect transistor (MOSFET). In an embodiment, transistor 3 may be an N-channel MOSFET.

The RF choke inductor 1 may block an RF signal from being transmitted from the input power source to the transistor 3 so that only DC is transmitted to the transistor 3.

The shunt capacitor 4 may be connected in parallel to the transistor 3 and may be discharged or charged while the transistor 3 is turned on or turned off. The shunt capacitor 4 may allow the power amplifier 10 to operate in a ZVS mode. The shunt capacitor 4 may be a separate capacitor connected in parallel to the transistor 3. In an embodiment, the shunt capacitor 4 may be internal capacitance (e.g., drain-source capacitance) of the transistor 3.

RF power may be generated based on whether the transistor 3 is turned on or turned off by receiving the input signal from the gate driver 2. For example, the transistor 3 may generate the RF power by turning on or off in response to the input signal received from the gate driver 2. The generated RF power may be transmitted to the filter circuit 13 and/or the multi-resonant circuit 15 through an output terminal of the transistor 3.

For example, when the transistor 3 is turned on, the transistor 3 may be interpreted as a short circuit to a ground, which is electrically shorted and connected to a source. In this case, a voltage at the output terminal of transistor 3 may be interpreted as 0. Current flowing through the RF choke inductor 1 to the transistor 3 may gradually increase.

When the transistor 3 is turned off, the current flowing through the RF choke inductor 1 may be directed to the shunt capacitor 4, and as the shunt capacitor 4 is gradually charged, the voltage at the output terminal of the transistor 3 (e.g., a voltage across the shunt capacitor 4) may increase until reaching a maximum value.

Thereafter, as the shunt capacitor 4 is gradually discharged, the current may flow from the shunt capacitor 4 through the output terminal of the transistor 3 to the filter circuit 13 and/or the multi-resonant circuit 15, and thus, the voltage across the shunt capacitor 4 may gradually decrease. After the transistor 3 is turned off and before the transistor 3 is turned on again (before the current starts flowing again through the RF choke inductor 1 to the transistor 3), the transistor 3, the shunt capacitor 4, and the input signal may be set such that the voltage at the output terminal of the transistor 3 (e.g., the voltage across the shunt capacitor 4 and a drain-source voltage of the transistor 3) gradually decreases to 0 and an amount of change by which the voltage at the output terminal of the transistor 3 decreases becomes 0.

When the transistor 3 is turned on again, the current flowing through the RF choke inductor 1 may be directed to the transistor 3, and while the transistor 3 is in an on state, the voltage at the output terminal of the transistor 3 may be maintained at 0. As described above, while the transistor 3 is in the on state, the voltage at the output terminal of the transistor 3 may be 0, and while the transistor 3 is in an off state, the current flowing through the RF choke inductor 1 may be directed to the shunt capacitor 4 so that the current flowing through the RF choke inductor 1 to the transistor 3 becomes 0.

Since there is no overlap between a time period in which the voltage at the output terminal of the transistor 3 is non-zero and a time period in which drain-source current is non-zero do not overlap, the power consumed by the transistor 3 may be ideally 0. However, in a non-ideal case, because RF power is generated based on whether the transistor 3 is turned on or turned off, the generated RF power may include not only a component of a desired frequency (e.g., a fundamental component of the operating frequency), but also a second or higher harmonic component. A duty cycle of the transistor 3 may be set to, for example, 50%, based on the input signal. For example, in a non-ideal case, the transistor 3 may generate RF power with not only a component of a desired frequency (e.g., a fundamental component of the operating frequency), but also a second or higher harmonic component of the operating frequency.

The filter circuit 13 may be connected between the output terminal of the transistor 3 (or a first node N1) and the ground. The filter circuit 13 may be connected in parallel to the transistor 3. The filter circuit 13 may be an inductor-capacitor (LC) series resonant circuit including a filter inductor (L2ω₀) 13a and a filter capacitor (C2ω₀) 13b connected in series to each other. The filter inductor 13a and the filter capacitor 13b may have appropriate element values such that a resonant frequency of the filter circuit 13 corresponds to a second harmonic frequency 200 of an operating frequency wo of the input signal. The filter circuit 13 may be interpreted as an electrical short circuit at the second harmonic frequency 2ω₀. As the filter circuit 13 is electrically shorted (i.e., is electrically short-circuited to the ground) at the second harmonic frequency 2ω₀, the filter circuit 13 may operate as a second harmonic filter that prevents a second harmonic component of the RF power generated from the transistor 3 from being transmitted to the multi-resonant circuit 15.

The multi-resonant circuit 15 may be connected in series to the output terminal of the transistor 3. One end of the multi-resonant circuit 15 may be connected to the output terminal of the transistor 3 (or the first node N1) and one end of the filter circuit 13, and the other end of the multi-resonant circuit 15 may be connected to one end of the matching network 20 (or a second node N2).

According to various embodiments, the multi-resonant circuit 15 may include a plurality of series resonant circuits. The plurality of series resonant circuits may be connected in parallel to each other. The plurality of series resonant circuits may have different resonant frequencies from each other. The plurality of series resonant circuits may each be an LC series resonant circuit.

The plurality of series resonant circuits may include a main series resonant circuit having a resonant frequency corresponding to the operating frequency ω₀ of the input signal (e.g., corresponding to a fundamental frequency (or a first harmonic frequency)), and at least one sub-series resonant circuit having a resonant frequency corresponding to a frequency in a peripheral band of the operating frequency ω₀. In an embodiment, the resonant frequency of the main series resonant circuit may be the operating frequency ω₀ of the input signal, and the resonant frequency of the at least one sub-series resonant circuit may be a frequency in the peripheral band of the operation frequency ω₀.

For example, referring to FIG. 2, the multi-resonant circuit 15 may include a first series resonant circuit 151, a second series resonant circuit 152, and a third series resonant circuit 153. The first series resonant circuit 151 may be a main series resonant circuit and may have a resonant frequency corresponding to the operating frequency ω₀. In an embodiment, the resonant frequency of the first series resonant circuit 151 may be the operating frequency ω₀. The second series resonant circuit 152 and the third series resonant circuit 153 may be sub-series resonant circuits and may each have a resonant frequency corresponding to a frequency in a peripheral band of the operating frequency ω₀. In an embodiment, the resonant frequency of each of the second and the third series resonant circuits 152 and 153 may be a frequency in a peripheral band of the operating frequency ω₀.

The first series resonant circuit 151 may include a first inductor (Lω₀) 151a and a first capacitor (Cω₀) 151b connected in series to each other. The first inductor 151a and the first capacitor 151b may have appropriate element values such that the resonant frequency of the first series resonant circuit 151 corresponds to the operating frequency ω₀. Accordingly, the multi-resonant circuit 15 may be interpreted as an electrical short circuit at the operating frequency ω₀. As the multi-resonant circuit 15 is electrically shorted (i.e., is electrically short-circuited to the second node N2 or the matching network 20) at the operating frequency ω₀, the multi-resonant circuit 15 may pass a fundamental component (or a first harmonic component) of the RF power generated from the transistor 3.

The second series resonant circuit 152 may include a second inductor (Lω′₀) 152a and a second capacitor (Cω′₀) 152b connected in series to each other. The second inductor 152a and the second capacitor 152b may have appropriate element values such that the resonant frequency of the second series resonant circuit 152 corresponds to a first peripheral frequency ω′₀ in a peripheral band of the operating frequency ω₀. Accordingly, the multi-resonant circuit 15 may be interpreted as an electrical short circuit at the first peripheral frequency ω′₀.

Likewise, the third series resonant circuit 153 may include a third inductor (Lω″₀) 153a and a third capacitor (Cω″₀) 153b connected in series to each other. The third inductor 153a and the third capacitor 153b may have appropriate element values such that the resonant frequency of the third series resonant circuit 153 corresponds to a second peripheral frequency ω″₀ in a peripheral band of the operating frequency ω₀. Accordingly, the multi-resonant circuit 15 may be interpreted as an electrical short circuit at the second peripheral frequency ω″₀.

A frequency in a peripheral band of the operating frequency ω₀ may be determined according to the operating frequency ω₀ and an operating bandwidth (%). The frequency in the peripheral band of the operating frequency ω₀ may be set to an appropriate value as necessary, considering the operating frequency ω₀ and the operating bandwidth (%). In an embodiment, the operating bandwidth may be set to 20%. For example, when the operating frequency ω₀ is 13.56 MHz and the operating bandwidth is 20%, the first peripheral frequency ω′₀ and the second peripheral frequency ω″₀ may be 12.20 MHz and 14.91 MHz, respectively.

FIG. 2 shows that the multi-resonant circuit 15 includes the first series resonant circuit 151 as one main series resonant circuit and the second series resonant circuit 152 and the third series resonant circuit 153 as two sub-series resonant circuits, and thus, a total of three series resonant circuits, that is, the first to third series resonant circuits 151 to 153, are connected in parallel to each other, but embodiments are not limited thereto. For example, the multi-resonant circuit 15 may include a total of five series resonant circuits, including one main series resonant circuit and four sub-series resonant circuits. As such, the number of the plurality of series resonant circuits provided in the multi-resonant circuit 15 may be adjusted according to the designer's intention, considering band characteristics, efficiency, element costs, etc.

As a comparative example, a class E power amplifier of the related art includes one LC resonant circuit connected in series to a transistor. The one LC resonant circuit is designed to resonate at an operating frequency and transmits only RF power of a desired frequency to a load. Accordingly, the class E power amplifier may have rapid performance degradation at peripheral frequencies other than the operating frequency.

The multi-resonant circuit 15 included in the power amplifier 10 according to various embodiments may include not only a main series resonant circuit having a resonant frequency corresponding to the operating frequency ω₀ but also at least one sub-series resonant circuit connected in parallel to the main series resonant circuit and having a resonant frequency corresponding to a frequency in a peripheral band of the operating frequency ω₀, and thus, the multi-resonant circuit 15 may operate as a short circuit not only at the operating frequency ω₀ but also at the frequency in the peripheral band of the operating frequency ω₀. As a result, the power amplifier 10 may maintain performance despite frequency changes and may improve band characteristics.

The matching network 20 may be connected between the power amplifier 10 and the load. The matching network 20 may provide impedance matching such that an impedance facing matching network 20 matches an impedance of the load. Referring to FIG. 2, the matching network 20 may match an input impedance Zₜₓ facing the matching network 20 in the power amplifier 10 with an impedance Z_{Load} of the load.

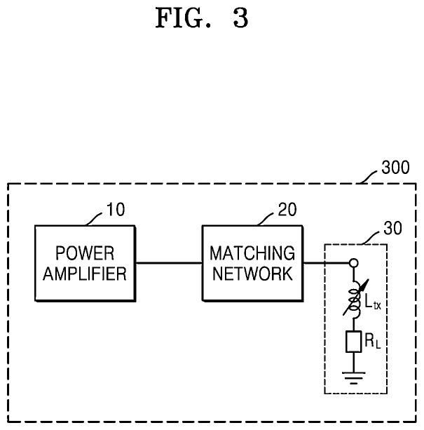

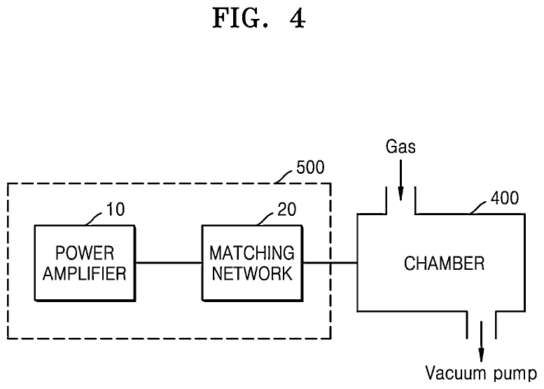

FIG. 3 is a diagram illustrating a wireless power transmission device 300 including the power amplifier 10, according to an embodiment, and FIG. 4 is a diagram illustrating an RF generator 500 including the power amplifier 10, according to an embodiment. The power amplifier 10 according to an embodiment, which has been described above with reference to FIG. 2, may be included in a wireless power transmission device and/or an RF generator to provide improved band characteristics.

Referring to FIG. 3, the wireless power transmission device 300 according to an embodiment may include the power amplifier 10, the matching network 20, and a power transmission circuit 30. As described above with reference to FIG. 2, the power amplifier 10 may include the multi-resonant circuit 15 (see FIG. 2), and thus, the performance of the wireless power transmission device 300 may be maintained despite frequency changes.

The power transmission circuit 30 may be connected between the matching network 20 and a ground. In an embodiment, the power transmission circuit 30 may include a transmission coil Lₜₓ and a coil resistor R_{L}. The coil resistor R_{L} may refer to a parasitic resistor of the transmission coil Lₜₓ. In an embodiment, DC power generated from an input power source may be converted into alternating current (AC) power in the power amplifier 10 and may be transmitted to the transmission coil Lₜₓ of the power transmission circuit 30 through the matching network 20. The power transmitted to the transmitting coil Lₜₓ may be transmitted to a wireless power reception device located outside and having the same resonant frequency.

A wireless power transmission method of the wireless power transmission device 300 according to an embodiment may include an operation in which the transistor 3 (see FIG. 2) included in the power amplifier 10 outputs a signal corresponding to the operating frequency ω₀ that has been set, based on an input signal and the driving voltage V_{DC} (see FIG. 2), an operation in which the matching network 20 converts an impedance (e.g., the input impedance Zₜₓ (see FIG. 2)) of the signal received from the power amplifier 10, an operation in which the power transmission circuit 30 receives the signal of which the impedance has been converted from the matching network 20 and forms a magnetic field based on the received signal, and an operation in which the multi-resonant circuit 15 (see FIG. 2), which includes a plurality of series resonant circuits having different resonant frequencies from each other and connected in parallel to each other, connects the transistor 3 (see FIG. 2) to the matching network 20.

Referring to FIG. 4, the RF generator 500 according to an embodiment may include the power amplifier 10 including the multi-resonant circuit 15 (see FIG. 2), which has been described above with reference to FIG. 2. Accordingly, the performance of the RF generator 500 may be maintained despite frequency changes. In an embodiment, the RF generator 500 may be for use in the semiconductor industry and may achieve high output (e.g., 1,000 W or more) at a frequency in the MHz unit.

The RF generator 500 may be connected to a chamber 400 (i.e., a semiconductor process chamber) located outside. That is, a load of the RF generator 500 may be the chamber 400, which is a semiconductor device located outside. Gas for a semiconductor process may be injected into the chamber 400, and a vacuum pump connected to the chamber 400 may pump the gas injected into the chamber 400. In an embodiment, pressure of the chamber 400 may be adjusted by adjusting a flow rate of the injected gas and an operation of the vacuum pump.

In an embodiment, a matcher (not shown) may be connected between an output terminal of the RF generator 500 and the chamber 400, and the matcher may match impedances such that RF power is transmitted efficiently. In this case, the RF generator 500, the matcher, and the chamber 400 may be connected to each other by wires to transmit RF power to each other.

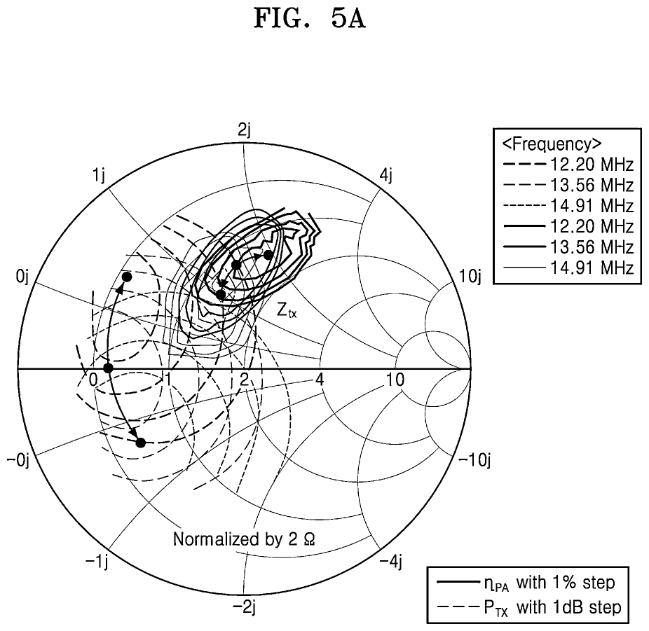

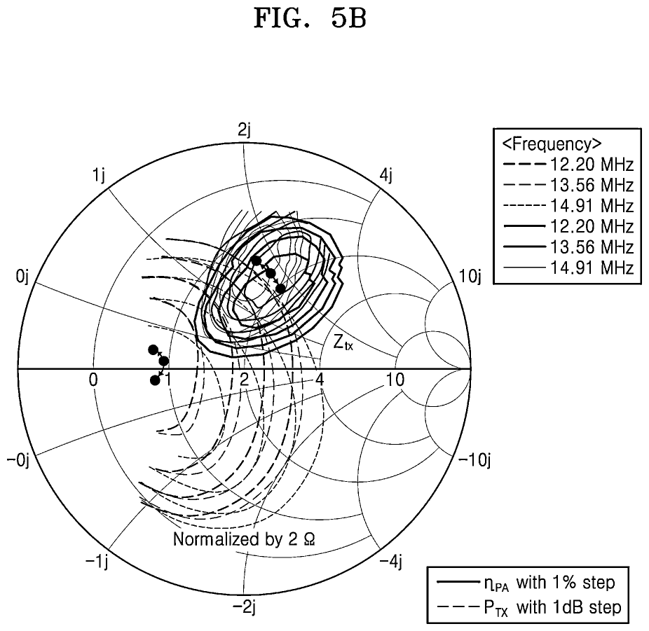

FIG. 5A is a Smith chart of a class E power amplifier of the related art as a comparative example, and FIG. 5B is a Smith chart of the power amplifier 10 included in the embodiment of FIG. 2. FIGS. 5A and 5B show a power P_{TX} contour and an efficiency η_{PA} contour of a power amplifier according to the operating frequency ω₀ (13.56 MHz) and frequencies in peripheral bands, that is, the first and second peripheral frequencies ω′₀ and ω″₀ (12.20 MHz and 14.91 MHz, respectively), with an operating bandwidth of 20%. In FIGS. 5A and 5B, dotted lines represent a power P_{TX} contour, and solid lines represent an efficiency η_{PA} contour.

Referring to FIG. 5A, in the class E power amplifier of the related art, a power P_{TX} contour and an efficiency η_{PA} contour of the input impedance Zₜₓ (FIG. 2) of a matching network according to the operating frequency ω₀ and the first and second peripheral frequencies ω′₀ and ω″₀ are spread out at the first and second peripheral frequencies ω′₀ and ω″₀ with respect to the operating frequency ω₀. As shown in FIG. 5A, in a case in which the power P_{TX} contour and efficiency η_{PA} contour vary greatly according to frequency, when the matching network is configured according to the operating frequency, it may be difficult to maintain equal performance in operating bandwidths other than the operating frequency. For example, when there is significant variation in both the power P_{TX} contour and the efficiency η_{PA} contour across different frequencies as shown in FIG. 5A, configuring the matching network according to the operating frequency may pose challenges in maintaining consistent performance across other frequencies within the operating bandwidth.

FIG. 5B shows a power P_{TX} contour and an efficiency η_{PA} contour of the embodiment of FIG. 2 in which the first to third series resonant circuits 151 to 153 are configured such that the first series resonant circuit 151 has a resonant frequency of 13.56 MHz, the second series resonant circuit 152 has a resonant frequency of 12.20 MHz, and the third series resonant circuit 153 has a resonant frequency of 14.91 MHz. Referring to FIG. 5B in comparison with FIG. 5A, in the power amplifier according to an embodiment, a power P_{TX} contour and an efficiency η_{PA} contour of the input impedance Zₜₓ (FIG. 2) of a matching network according to the operating frequency ω₀ and the first and second peripheral frequencies ω′₀ and ω″₀ are relatively constant at the operating frequency ω₀ and the first and second peripheral frequencies ω′₀ and ω″₀.

As shown in FIG. 5B, in a case in which the power P_{TX} contour and efficiency η_{PA} contour are gathered rather than spread out, the input impedance Zₜₓ (see FIG. 2) of the matching network may be selected as one point, and the matching network may be configured based on the operating frequency ω₀. Accordingly, the power amplifier may operate with equal performance not only at the operating frequency ω₀ but also at a frequency in the operating bandwidth. For example, when the power P_{TX} contour and efficiency η_{PA} contour are concentrated rather than dispersed, the input impedance Zₜₓ (refer to FIG. 2) of the matching network can be chosen as a single point, and the matching network can be designed according to the operating frequency ω0, allowing the power amplifier to maintain consistent performance not only at the operating frequency ω₀ but also across frequencies within the operating bandwidth of the operating frequency ω₀.

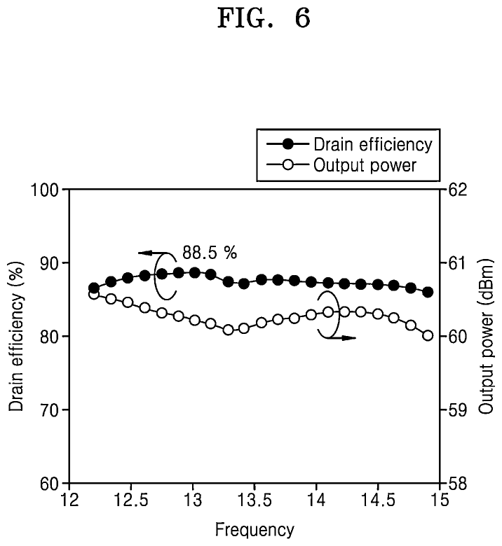

FIG. 6 is a diagram illustrating efficiency and power according to frequency of the power amplifier 10 according to an embodiment. FIG. 6 shows drain efficiency and output power of the power amplifier 10 in a case in which the operating frequency is set to 13.56 MHz in the embodiment of FIG. 2, like in FIG. 5B. Here, the drain efficiency of the power amplifier 10 refers to drain power compared to applied power (i.e., drain power divided by applied power).

Referring to FIG. 6, the drain efficiency of the power amplifier 10 is about 88.5% and is maintained constant not only at the operating frequency (13.56 MHz) but also at a frequency in a peripheral band. The output power of the power amplifier 10 is also maintained relatively constant at 60 dBm or more at the operating frequency and a frequency in a peripheral band.

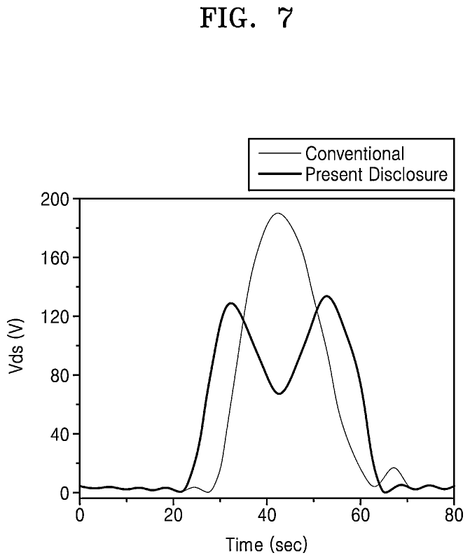

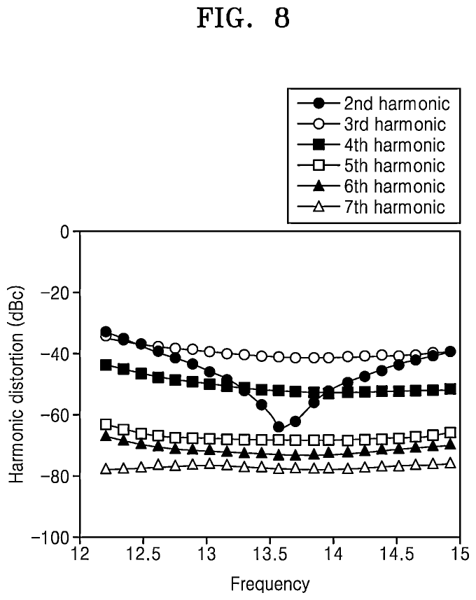

FIG. 7 is a diagram illustrating amplitude magnitudes of drain voltages V_{ds} of a class E power amplifier and a power amplifier according to an embodiment, and FIG. 8 is a diagram illustrating a harmonic output power level according to frequency of the power amplifier according to an embodiment.

In FIG. 7, “Conventional” represents a drain voltage V_{ds} of a power amplifier of the related art (e.g., a class E power amplifier), and “Present Disclosure” represents a drain voltage V_{ds} of the power amplifier according to an embodiment (e.g., the power amplifier 10 of FIG. 2). FIG. 7 is a graph showing a case in which a DC voltage of 50 V is applied to an output terminal of a transistor of a power amplifier.

Referring to FIG. 7, in the power amplifier of the related art, the amplitude magnitude of the drain voltage V_{ds} is about 186 V, which is about 3.7 times the magnitude of the DC voltage applied to the output terminal of the transistor. In contrast, in the power amplifier according to an embodiment, a second harmonic component is controlled due to the inclusion of the filter circuit 13 (see FIG. 2), and thus, the amplitude magnitude of the drain voltage V_{ds} is reduced to about 130 V by about 30% reduction compared to the power amplifier of the related art. The filter circuit 13 may serve to smooth the waveform of the drain voltage V_{ds} over time. In the power amplifier according to an embodiment, the amplitude magnitude of the drain voltage V_{ds} of the transistor may be reduced so that the burden on the transistor is reduced, thereby enabling a stable operation.

Referring to FIG. 8, in the power amplifier according to an embodiment, due to the inclusion of the filter circuit 13 (see FIG. 2) that operates as a second harmonic short circuit, a harmonic power level generated at the output terminal of the transistor may be reduced.

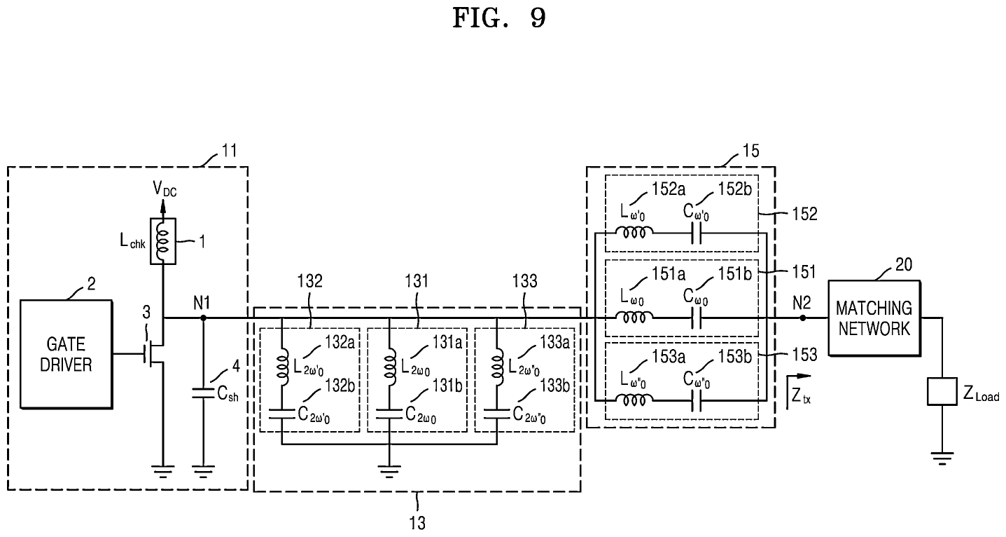

FIG. 9 is a diagram illustrating components of the filter circuit 13 included in the power amplifier 10, according to an embodiment. In FIG. 9, the same reference numerals as those in FIG. 2 denote the same components, and thus, redundant descriptions thereof will be omitted, and differences therebetween will be mainly described.

The filter circuit 13 may include a plurality of harmonic filter circuits. The plurality of harmonic filter circuits may be connected in parallel to each other. The plurality of harmonic filter circuits may each be connected between the output terminal of the transistor 3 and the ground. The plurality of harmonic filter circuits may have different resonant frequencies from each other. The plurality of harmonic filter circuits may each be an LC series resonant circuit.

The plurality of harmonic filter circuits may include a main harmonic filter circuit having a resonant frequency corresponding to the second harmonic frequency 2ω₀ of the operating frequency wo of the input signal, and at least one sub-harmonic filter circuit having a resonant frequency corresponding to a frequency in a peripheral band of the second harmonic frequency 2ω₀. In an embodiment, the resonant frequency of the main harmonic filter circuit may be the second harmonic frequency 2ω₀ of the operating frequency ω₀ of the input signal. A frequency of a peripheral band of the second harmonic frequency 2ω₀ of the operating frequency ω₀ may be determined according to the second harmonic frequency 2ω₀ and the operating bandwidth (%). In an embodiment, the resonant frequency of the at least one sub-harmonic filter circuit may be a frequency in the peripheral band of the second harmonic frequency 2ω₀.

For example, referring to FIG. 9, the plurality of harmonic filter circuits may include a first harmonic filter circuit 131, a second harmonic filter circuit 132, and a third harmonic filter circuit 133. The first harmonic filter circuit 131 may be a main harmonic filter circuit and may have a resonant frequency corresponding to the second harmonic frequency 2ω₀ of the operating frequency ω₀. In an embodiment, the resonant frequency of the first harmonic filter circuit 131 may be the second harmonic frequency 2ω₀ of the operating frequency ω₀. The second harmonic filter circuit 132 and the third harmonic filter circuit 133 may be sub-harmonic filter circuits and may each have a resonant frequency corresponding to a frequency in a peripheral band of the second harmonic frequency 2ω₀. In an embodiment, the resonant frequency of each of the second harmonic filter circuit 132 and the third harmonic filter circuit 133 may be a frequency in the peripheral band of the second harmonic frequency 2ω₀.

The first harmonic filter circuit 131 may include a fourth inductor (L2ω₀) 131a and a fourth capacitor (C2ω₀) 131b connected in series to each other. The fourth inductor 131a and the fourth capacitor 131b may have the same configurations as those of the filter inductor 13a and filter capacitor 13b of FIG. 2, respectively. The fourth inductor 131a and the fourth capacitor 131b may have appropriate element values such that the resonant frequency of the first harmonic filter circuit 131 corresponds to the second harmonic frequency 2ω₀ of the operating frequency ω₀. Accordingly, the filter circuit 13 may be interpreted as an electrical short circuit at the second harmonic frequency 2ω₀ of the operating frequency ω₀.

The second harmonic filter circuit 132 may include a fifth inductor (L2ω′₀) 132a and a fifth capacitor (C2ω′₀) 132b connected in series to each other. The fifth inductor 132a and the fifth capacitor 132b may have appropriate element values such that the resonant frequency of the second harmonic filter circuit 132 corresponds to a first frequency 2ω′₀ in a peripheral band of the second harmonic frequency 2ω₀. Accordingly, the filter circuit 13 may be interpreted as an electrical short circuit at the first frequency 2ω′₀.

The third harmonic filter circuit 133 may include a sixth inductor (L2ω″₀) 133a and a sixth capacitor (C2ω″₀) 133b connected in series to each other. The sixth inductor 133a and the sixth capacitor 133b may have appropriate element values such that the resonant frequency of the third harmonic filter circuit 133 corresponds to a second frequency 2ω″₀ in a peripheral band of the second harmonic frequency 2ω₀. Accordingly, the filter circuit 13 may be interpreted as an electrical short circuit at the second frequency 2ω″₀.

The filter circuit 13 included in the power amplifier 10 according to an embodiment may include not only a main harmonic filter circuit having a resonant frequency corresponding to the second harmonic frequency 2ω₀ of the operating frequency ω₀ but also at least one sub-harmonic filter circuit connected in parallel to the main harmonic filter circuit and having a resonant frequency corresponding to a frequency in a peripheral band of the second harmonic frequency 2ω₀, and thus, the power amplifier 10 may operate as a short circuit not only at the second harmonic frequency 2ω₀ but also at the frequency in the peripheral band of the second harmonic frequency 2ω₀. As a result, band characteristics may be improved in second harmonic control of the power amplifier 10.

FIG. 9 shows that the filter circuit 13 includes the first harmonic filter circuit 131 as one main harmonic filter circuit and the second harmonic filter circuit 132 and the third harmonic filter circuit 133 as two sub-harmonic filter circuits, and thus, a total of three harmonic filter circuits, that is, the first to third harmonic filter circuits 131 to 133, are connected in parallel to each other, but embodiments are not limited thereto. For example, the filter circuit 13 may include a total of five harmonic filter circuits, including one main harmonic filter circuit and four sub-harmonic filter circuits. As such, the number of the plurality of harmonic filter circuits provided in the filter circuit 13 may be adjusted according to the designer's intention, considering band characteristics, efficiency, element costs, etc.

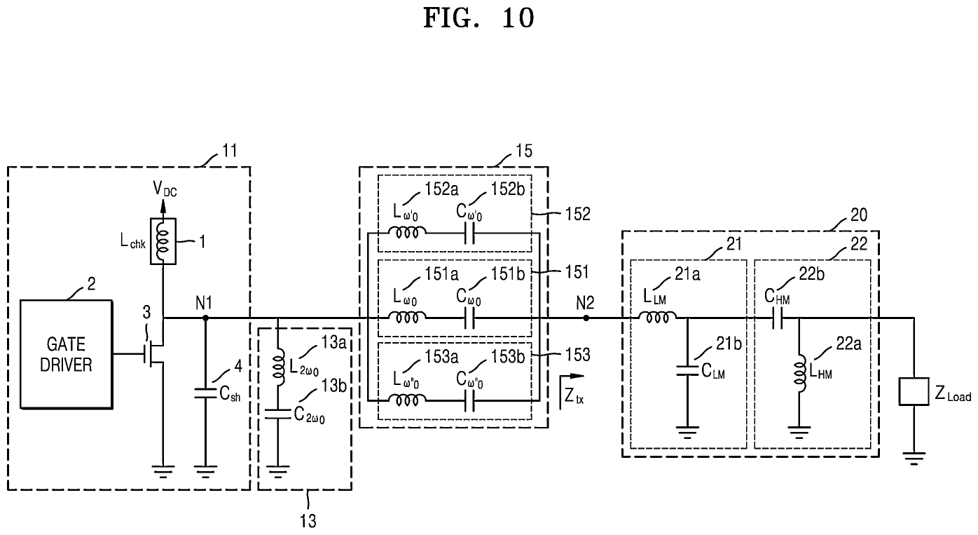

FIG. 10 is a diagram illustrating components of the matching network 20 connected to the power amplifier 10, according to an embodiment. In FIG. 10, the same reference numerals as those in FIG. 2 denote the same components, and thus, redundant descriptions thereof will be omitted.

Referring to FIG. 10, in an embodiment, the matching network 20 may include a low-pass filter 21 and a high-pass filter 22. The configuration of the low-pass filter 21 and the high-pass filter 22 in the matching network 20 may improve band characteristics. The low-pass filter 21 may include a seventh inductor (L_{LM}) 21a and a seventh capacitor (C_{LM}) 21b, and the high-pass filter 22 may include an eighth inductor (L_{HM}) 22a and an eighth capacitor (C_{HM}) 22b.

One end of the seventh inductor 21a may be connected to the multi-resonant circuit 15, and the other end of the seventh inductor 21a may be connected to the seventh capacitor 21b and the eighth capacitor 22b. One end of the seventh capacitor 21b may be connected to the seventh inductor 21a and the eighth capacitor 22b, and the other end of the seventh capacitor 21b may be connected to the ground. One end of the eighth capacitor 22b may be connected to the seventh inductor 21a and the seventh capacitor 21b, and the other end of the eighth capacitor 22b may be connected to the eighth inductor 22a and the load. One end of the eighth inductor 22a may be connected to the eighth capacitor 22b and the load, and the other end of the eighth inductor 22a may be connected to the ground.

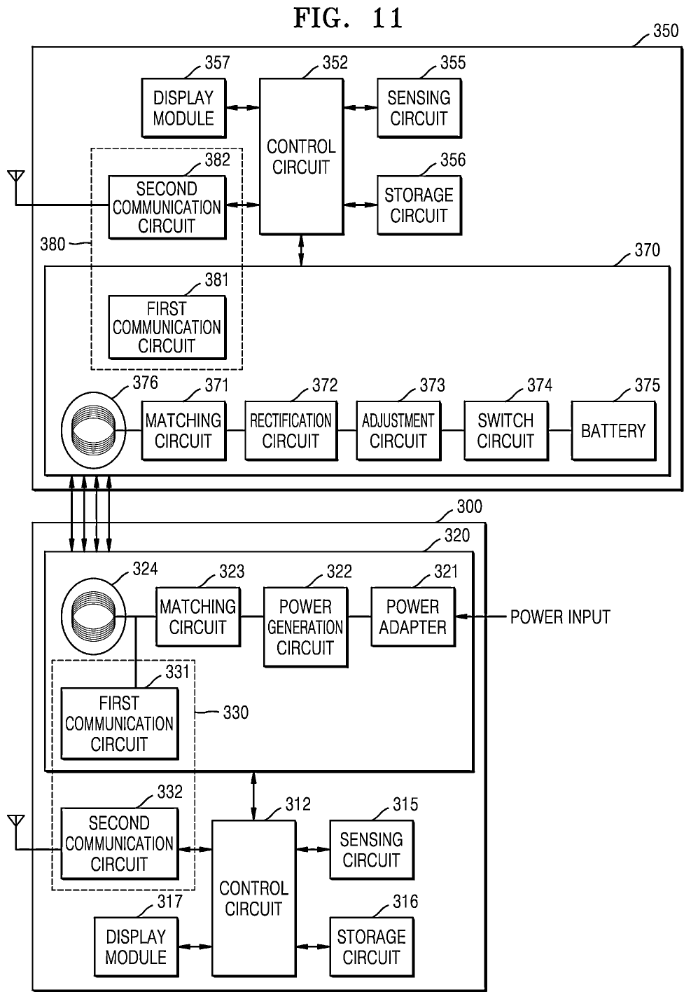

FIG. 11 is a block diagram illustrating the wireless power transmission device 300 and a wireless power reception device 350, according to an embodiment. Referring to FIG. 11, the wireless power transmission device 300 may include a power transmitter 320, a control circuit 312, a communication circuit 330, a sensing circuit 315, and/or a storage circuit 316.

The wireless power transmission device 300 may provide power to the wireless power reception device 350 through the power transmitter 320. For example, the wireless power transmission device 300 may transmit power according to a resonance method. When power is transmitted by the resonance method, the wireless power transmission device 300 may be implemented by a method defined in, for example, the Alliance for Wireless Power (A4WP) standard (or the Air Fuel Alliance (AFA) standard). The wireless power transmission device 300 may include a conductive pattern 324 capable of generating an induced magnetic field (e.g., a Tx field) when AC flows therethrough according to a resonance method or an induction method. The transmission coil Lₜₓ of FIG. 2 may correspond to the conductive pattern 324 of FIG. 11. A process in which the wireless power transmission device 300 generates a magnetic field through the conductive pattern 324 may correspond to outputting wireless power, and a process in which an induced electromotive force is generated in the wireless power reception device 350, based on the magnetic field (e.g., a Tx field) generated through the conductive pattern 324, may correspond to receiving wireless power. Through such processes, the wireless power transmission device 300 wirelessly transmits power to the wireless power reception device 350. The wireless power reception device 350 may include a conductive pattern 376 in which an induced electromotive force is generated by a magnetic field formed around the conductive pattern 376 and having a size that changes over time. A process in which, as an induced electromotive force is generated in the conductive pattern 376 of the wireless power reception device 350, AC is output from the conductive pattern 376 or an AC voltage is applied to the conductive pattern 376 may correspond to the wireless power reception device 350 receiving power wirelessly. In an embodiment, the wireless power transmission device 300 may transmit power according to an induction method. When power is transmitted by the induction method, the wireless power transmission device 300 may operate in a method defined in, for example, the Wireless Power Consortium (WPC) standard (or the Qi standard).

The power transmitter 320 may include a power adapter 321, a power generation circuit 322, a matching circuit 323, the conductive pattern 324, or a first communication circuit 331. According to various embodiments, the power transmitter 320 may be configured to wirelessly transmit power to the wireless power reception device 350 through the conductive pattern 324. According to various embodiments, the power transmitter 320 may receive power from the outside in the form of a DC or AC waveform and may supply the received power to the wireless power reception device 350 in the form of an AC waveform.

The power adapter 321 may receive AC or DC power from the outside or receive a power signal from a battery device and may output DC power having a set voltage value. According to various embodiments, the voltage value of the DC power output from the power adapter 321 may be controlled by the control circuit 312. According to various embodiments, the DC power output from the power adapter 321 may be output to the power generation circuit 322.

The power generation circuit 322 may convert DC output from the power adapter 321 into AC and output the AC. The power generation circuit 322 may include an amplifier. The power generation circuit 322 may include the power amplifier 10 as described above with reference to FIG. 2.

When DC input through the power adapter 321 is less than a set gain, the power generation circuit 322 may amplify the DC with the set gain by using the amplifier. In an embodiment, the power generation circuit 322 may include a circuit for converting DC input from the power adapter 321 into AC, based on a control signal input from the control circuit 312 (i.e., in response to the control signal input of the control circuit 312). For example, the power generation circuit 322 may convert DC input from the power adapter 321 into AC through an inverter (not shown). In an embodiment, the power generation circuit 322 may include a gate driving device (e.g., the gate driver 2 in FIG. 2). As the gate driving device controls DC input from the power adapter 321 by turning the DC on/off, the DC may be converted into AC. In an embodiment, the power generation circuit 322 may generate an AC power signal through a wireless power generator (e.g., an oscillator).

The matching circuit 323 may perform impedance matching. The matching circuit 323 of FIG. 11 may correspond to the matching network 20 of FIG. 2. Through impedance adjustment, the matching circuit 323 may control output power transmitted to the wireless power reception device 350 through the conductive pattern 324 to have high efficiency or high output. According to various embodiments, the matching circuit 323 may adjust an impedance based on control by the control circuit 312. The matching circuit 323 may include at least one of an inductor, a capacitor, and a switch device. The control circuit 312 may control a connection state with at least one of an inductor and a capacitor through a switch device, and thus, impedance matching may be performed.

The first communication circuit 331 may perform communication in an in-band format by using an electromagnetic wave generated by the conductive pattern 324.

The sensing circuit 315 may sense a change in current/voltage applied to the conductive pattern 324 of the power transmitter 320. According to the change in current/voltage applied to the conductive pattern 324, an amount of power to be transmitted to the wireless power reception device 350 may be changed. In an embodiment, the sensing circuit 315 may sense a change in temperature of the wireless power transmission device 300. According to various embodiments, the sensing circuit 315 may include at least one of a current/voltage sensor and a temperature sensor.

The control circuit 312 may control an operation of the wireless power transmission device 300. For example, the control circuit 312 may control the operation of the wireless power transmission device 300 by using an algorithm, a program, or an application required for control, which is stored in the storage circuit 316. The control circuit 312 may be implemented in the form of a central processing unit (CPU), a microprocessor, or a minicomputer. For example, the control circuit 312 may display a state of the wireless power reception device 350 on a display module 317, based on a message received from the wireless power reception device 350 through the communication circuit 330.

The control circuit 312 may control the wireless power transmission device 300 to wirelessly transmit power to the wireless power reception device 350 through the power transmitter 320. According to various embodiments, the control circuit 312 may control the wireless power transmission device 300 to wirelessly receive information from the wireless power reception device 350 through the communication circuit 330.

The control circuit 312 may control the wireless power transmission device 300 to generate or transmit power to the wireless power reception device 350, based on the information received from the wireless power reception device 350. In an embodiment, the control circuit 312 may determine or change an amount of power transmitted to the wireless power reception device 350, based on the information received from the wireless power reception device 350. In an embodiment, the control circuit 312 may control the matching circuit 323 to change an impedance.

The display module 317 may display general information related to a state, environment information, or a charging state of the wireless power transmission device 300.

The communication circuit 330 may communicate with the wireless power reception device 350 using a protocol. The communication circuit 330 may perform data communication with a communication circuit 380 of the wireless power reception device 350. For example, the communication circuit 330 may unicast, multicast, or broadcast a signal.

In an embodiment, the communication circuit 330 may include at least one of the first communication circuit 331, which is implemented as a single hardware component with the power transmitter 320 and allows the wireless power transmission device 300 to communicate in an in-band format, and a second communication circuit 332, which is implemented as a hardware component different from the power transmitter 320 and allows the wireless power transmission device 300 to communicate in an out-of-band format.

According to various embodiments, the wireless power reception device 350 may include a power receiver 370, a control circuit 352, the communication circuit 380, a sensing circuit 355, a storage circuit 356, and/or a display module 357. The communication circuit 380 may include a first communication circuit 381 and a second communication circuit 382.

According to various embodiments, the power receiver 370 may receive power from the power transmitter 320 of the wireless power transmission device 300. The power receiver 370 may be implemented in the form of a built-in battery or may be implemented in the form of a power reception interface to receive power from the outside. The power receiver 370 may include a matching circuit 371, a rectification circuit 372, an adjustment circuit 373, a battery 375, and/or the conductive pattern 376.

According to various embodiments, the power receiver 370 may receive wireless power in the form of an electromagnetic wave, which is generated in response to current/voltage applied to the conductive pattern 324 of the power transmitter 320, through the conductive pattern 376. For example, the power receiver 370 may receive power by using induced electromotive forces generated in the conductive pattern 324 of the power transmitter 320 and the conductive pattern 376 of the power receiver 370.

The matching circuit 371 may perform impedance matching. The matching circuit 371 may adjust an impedance based on control by the control circuit 352. The rectification circuit 372 may rectify wireless power, which is received by the conductive pattern 376, in the form of DC and may be implemented, for example, in the form of a bridge diode. The adjustment circuit 373 may convert the rectified power to a set gain. The adjustment circuit 373 may include a DC/DC converter (not shown). A switch circuit 374 may connect the adjustment circuit 373 to the battery 375. The switch circuit 374 may be maintained in an on/off state under control by the control circuit 352. The battery 375 may be charged by receiving power input from the adjustment circuit 373.

The sensing circuit 355 may sense a change in state of power received by the wireless power reception device 350. For example, the sensing circuit 355 may periodically or aperiodically measure a current/voltage value received by the conductive pattern 376 through a current/voltage sensor (not shown).

The display module 357 may display general information related to a charging state of the wireless power reception device 350.

The communication circuit 380 may communicate with the wireless power transmission device 300 using a protocol. The communication circuit 380 may perform data communication with the communication circuit 330 of the wireless power transmission device 300.

The control circuit 352 may transmit charging setting information for receiving a required amount of power, based on information related to a battery state of the wireless power reception device 350, to the wireless power transmission device 300 through the communication circuit 380. The control circuit 352 may transmit power amount control information for controlling an amount of power received from the wireless power transmission device 300, according to a change in amount of power charged in the wireless power reception device 350, to the wireless power transmission device 300 through the communication circuit 380. The control circuit 352 may transmit environment information according to a change in charging environment of the wireless power reception device 350 to the wireless power transmission device 300 through the communication circuit 380. For example, when a value of temperature data measured by the sensing circuit 355 is greater than or equal to a set temperature reference value, the control circuit 352 may transmit the measured temperature data to the wireless power transmission device 300.

The power amplifier 10 (see FIG. 2) according to an embodiment may include the multi-resonant circuit 15 (see FIG. 2) in which a plurality of series resonant circuits are connected in parallel to each other, thereby providing stable performance not only at the operating frequency but also at a frequency in a peripheral band. In addition, the power amplifier 10 (see FIG. 2) may include the filter circuit 13 (see FIGS. 2 and 9) so that the lifespan of the transistor 3 (see FIGS. 2 and 9) is extended, and thus, the lifespan of an electronic device using the power amplifier 10 may be extended. The power amplifier 10 may be used in various electronic devices, such as the wireless power transmission device 300 (see FIG. 3) and the RF generator 500 (see FIG. 4), which has with high output for use in the semiconductor industry, thereby contributing to stable wired/wireless power transmission.

In a power amplifier, an RF generator, and a wireless power transmission device according to the present disclosure, the power amplifier may include a multi-resonant circuit in which a plurality of series resonant circuits are connected in parallel to each other, and thus, band characteristics may be improved.

While the present disclosure has been particularly shown and described with reference to embodiments thereof, it will be understood that various changes in form and details may be made therein without departing from the spirit and scope of the following claims.

What is claimed is:

1. A power amplifier comprising:
a switch circuit comprising a transistor configured to be turned on or turned off in response to an input signal;
a filter circuit connected between an output terminal of the transistor and a ground; and
a multi-resonant circuit connected to the output terminal of the transistor and one end of the filter circuit and comprising a plurality of series resonant circuits, the plurality of series resonant circuits having different resonant frequencies from each other and being connected in parallel to each other.

2. The power amplifier of claim 1,
wherein each of the plurality of series resonant circuits is an inductor-capacitor (LC) series resonant circuit.

3. The power amplifier of claim 1,
wherein the switch circuit further comprises a gate driver and a radio frequency (RF) choke inductor, the gate driver being connected to a gate of the transistor, and the RF choke inductor being connected to the output terminal of the transistor, and
wherein the transistor is further configured to receive a driving voltage applied through the RF choke inductor and output, in response to the input signal applied through the gate driver, a signal having an operating frequency.

4. The power amplifier of claim 3,
wherein the plurality of series resonant circuits comprise:
a main series resonant circuit having a resonant frequency which is the operating frequency; and
at least one sub-series resonant circuit having a resonant frequency which is a frequency in a peripheral band of the operating frequency.

5. The power amplifier of claim 3,
wherein the filter circuit comprises a plurality of harmonic filter circuits connected in parallel to each other and having different resonant frequencies from each other.

6. The power amplifier of claim 5,
wherein each of the plurality of harmonic filter circuits is an inductor-capacitor (LC) series resonant circuit.

7. The power amplifier of claim 5,
wherein the plurality of harmonic filter circuits comprise:
a main harmonic filter circuit having a resonant frequency which is a second harmonic frequency of the operating frequency; and
at least one sub-harmonic filter circuit having a resonant frequency which is a frequency in a peripheral band of the second harmonic frequency.

8. The power amplifier of claim 1,
wherein the transistor is further configured to operate in zero voltage switching (ZVS).

9. The power amplifier of claim 1,
wherein the switch circuit further comprises a shunt capacitor connected in parallel to the transistor.

10. A wireless power transmission device comprising:
a power amplifier comprising a switch circuit, a filter circuit, and a multi-resonant circuit and configured to:
convert a direct current received from an input power source into an alternating current having an operating frequency, and
perform zero voltage switching (ZVS);
a power transmission circuit comprising a transmission coil configured to transmit power received from the power amplifier to outside; and
a matching network connected between the power amplifier and the power transmission circuit and configured to match an impedance of the power amplifier with an impedance of the power transmission circuit,
wherein the multi-resonant circuit is connected between one end of the filter circuit and one end of the matching network and comprises a plurality of series resonant circuits, the plurality of series resonant circuits having different resonant frequencies from each other and being connected in parallel to each other.

11. The wireless power transmission device of claim 10,
wherein the switch circuit comprises:
a transistor configured to be turned on or turned off according to an input signal and operate in ZVS;
a gate driver connected to the transistor and configured to generate a driver signal to drive the transistor; and
a shunt capacitor connected in parallel to the transistor.

12. The wireless power transmission device of claim 11,
wherein the filter circuit is connected in parallel to the transistor.

13. The wireless power transmission device of claim 10,
wherein the plurality of series resonant circuits comprise:
a main series resonant circuit having a resonant frequency which is the operating frequency; and
at least one sub-series resonant circuit having a resonant frequency which is a frequency in a peripheral band of the operating frequency.

14. The wireless power transmission device of claim 10,
wherein the filter circuit comprises a plurality of harmonic filter circuits connected in parallel to each other and having different resonant frequencies from each other.

15. The wireless power transmission device of claim 14,
wherein the plurality of harmonic filter circuits comprise:
a main harmonic filter circuit having a resonant frequency which is a second harmonic frequency of the operating frequency; and
at least one sub-harmonic filter circuit having a resonant frequency which is a frequency in a peripheral band of the second harmonic frequency.

16. A radio frequency (RF) generator comprising:
a power amplifier comprising a switch circuit, a filter circuit, and a multi-resonant circuit and configured to convert a direct current received from an input power source into an alternating current having an operating frequency, and perform zero voltage switching (ZVS); and
a matching network connected between the power amplifier and a semiconductor process chamber and configured to match an impedance of the power amplifier to an impedance of the semiconductor process chamber,
wherein the multi-resonant circuit is connected between one end of the filter circuit and one end of the matching network and comprises a plurality of series resonant circuits, the plurality of series resonant circuits having different resonant frequencies from each other and being connected in parallel to each other.

17. The RF generator of claim 16,
wherein the switch circuit comprises:
a transistor configured to receive the direct current as a driving voltage and output, in response to an input signal, the alternating current having the operating frequency; and
a gate driver configured to apply the input signal to the transistor.

18. The RF generator of claim 17,
wherein the multi-resonant circuit includes:
a main series resonant circuit having a resonant frequency which is the operating frequency and configured to be short-circuited to the matching network at the operating frequency, and
at least one sub-series resonant circuit having a resonant frequency which is a frequency in a peripheral band of the operating frequency and configured to be short-circuited to the matching network at the frequency in the peripheral band of the operating frequency.

19. The RF generator of claim 17,
wherein the filter circuit includes:
a main harmonic filter circuit having a resonant frequency which is a second harmonic frequency of the operating frequency and configured to be short-circuited to a ground at the second harmonic frequency, and
at least one sub-harmonic filter circuit having a resonant frequency which is a frequency in a peripheral band of the second harmonic frequency and configured to be short-circuited to the ground at the frequency in the peripheral band of the second harmonic frequency.

20. The RF generator of claim 16,
wherein the matching network comprises an inductor-capacitor (LC) low-pass filter and an LC high-pass filter,
wherein one end of a capacitor of the LC high-pass filter is connected between an inductor and a capacitor of the LC low-pass filter, and
wherein the other end of the capacitor of the LC high-pass filter is connected to an inductor of the LC high-pass filter.
